(19) United States
(12) Patent Application Publication
(10) Pub. No.: US 2023/0167579 A1
(43) Pub. Date: Jun. 1, 2023

(54) METHOD OF ENHANCING SILICON CARBIDE MONOCRYSTALLINE GROWTH YIELD

(71) Applicant: NATIONAL CHUNG SHAN INSTITUTE OF SCIENCE AND TECHNOLOGY, Taoyuan City (TW)

(72) Inventors: CHIH-WEI KUO, Hsinchu City (TW); CHENG-JUNG KO, New Taipei City (TW); HSUEH-I CHEN, Taoyuan City (TW); JUN-BIN HUANG, Taoyuan City (TW); CHIA-HUNG TAI, New Taipei City (TW)

(21) Appl. No.: 17/537,521

(22) Filed: Nov. 30, 2021

(51) Int. Cl. C30B 23/06; C30B 29/36; C30B 35/00

(52) U.S. Cl. CPC C30B 23/066; C30B 29/36; C30B 35/002

(57) ABSTRACT

Provided is a method of enhancing silicon carbide monocrystalline growth yield, including the steps of: (A) filling a bottom of a graphite crucible with a silicon carbide raw material selected; (B) performing configuration modification on a graphite seed crystal platform; (C) fastening a silicon carbide seed crystal to the modified graphite seed crystal platform with a graphite clamping accessory; (D) placing the graphite crucible containing the silicon carbide raw material and the silicon carbide seed crystal in an inductive high-temperature furnace; (E) performing silicon carbide crystal growth process by physical vapor transport; and (F) obtaining silicon carbide monocrystalline crystals. The geometric configuration of the surface of the graphite seed crystal platform is modified to eradicate development of peripheral grain boundary.

### BACKGROUND OF THE INVENTION

### 1. Field of the Invention

The present disclosure relates to methods of enhancing silicon carbide monocrystalline growth yield, and in particular to a method of enhancing silicon carbide monocrystalline growth yield, advantageous in that geometric configuration of the surface of a graphite seed crystal platform is modified to eradicate development of peripheral grain boundary.

### 2. Description of the Related Art

In recent years, third-generation semiconductors, also known as wide bandgap semiconductors, such as silicon carbide (SiC) and gallium nitride (GaN), are deemed important by the industrial sector and mass media and applied mostly to power semiconductor components. Power semiconductors used to play an auxiliary role in the semiconductor industry. However, nowadays, power semiconductors with high conversion efficiency are required by emerging energy-saving industries, such as electric vehicles, solar power, DC power supply, and charging stations, to meet the demand for energy saving and carbon reduction.

Silicon carbide wafers are mainly of two sizes, namely semi-insulation 6 inches and n-type 6 inches. The two types of sizes of silicon carbide wafers are dedicated to 5G communication market and electric vehicle market, respectively, which are currently the targets of market developers. The two types of sizes of silicon carbide wafers differ significantly in specifications, for example, in terms of electrical properties and axial direction of wafers, but both of them are confronted with the same problem when it comes to crystal growth, that is, crystal peripheral defect formation and resultant decrease in available area. In general, defect-ridden area accounts for 10˜30% of the total area of commercially-available research-level silicon carbide wafers. Related papers and experience in growing silicon carbide crystal show that plenty defects appear in crystal periphery in a complicated growth environment because of the contact between the crystal periphery and graphite in the course of crystal growth, indicating that the defect-ridden area is mostly located at the periphery of the wafer.

Nowadays, silicon carbide crystal growth is carried out by Modified-Lely crystal growth technique with a graphite crucible which contains silicon carbide seed crystal and a silicon carbide raw material, using graphite components each processed by patented techniques. The silicon carbide seed crystal is fixed to a graphite seed crystal platform and then placed on the top of the graphite crucible, whereas the silicon carbide raw material is placed at the bottom of the graphite crucible. The silicon carbide seed crystal is fixed in place in two ways: applying adhesive and physical clamping (shown in FIG. 1).

The technique of applying adhesive involves coating a non-growth surface of a silicon carbide seed crystal 2 with a graphite adhesive 3, affixing the surface to a graphite seed crystal platform 1, and fixing the silicon carbide seed crystal 2 to the graphite seed crystal platform 1 by progressive heating.

The technique of physical clamping involves designing a configuration of the graphite seed crystal platform 1 and fixing the silicon carbide seed crystal 2 to the graphite seed crystal platform 1 with a graphite clamping accessory 4 by a means of screwing.

The technique of applying adhesive was devised earlier than the technique of physical clamping. The technique of applying adhesive traditionally required using sucrose as a binding agent but nowadays mostly requires using graphite adhesive to serve the purpose of binding. The most important feature of the technique of applying adhesive is the preparation of the adhesive. The difficulty in handling the adhesive is illustrated by FIG. 2, which shows that the graphite adhesive 3 produces a gas when undergoing curing at high temperature; the gas thus produced is confined to between the silicon carbide seed crystal 2 and the graphite seed crystal platform 1 and thus cannot be discharged, thereby leading to formation of plenty gas pores 5 between the silicon carbide seed crystal 2 and the graphite seed crystal platform 1. Owing to the gas pores 5, the silicon carbide seed crystal 2 undergoing crystal growth is disadvantaged by uneven distribution of temperature and thus the resultant formation of defects of microtubes 7 in the monocrystalline silicon carbide 6 thus grown. More badly, it is difficult to control the distribution of the gas pores 5 thus formed; thus, it is difficult to stabilize the uniformity of the graphite adhesive 3, leading to excessive stress difference in the contact between the silicon carbide seed crystal 2 and the graphite seed crystal platform 1. The excessive stress difference affects the crystal growth accumulation process, leading to an increase in defect distribution density.

As shown in FIG. 3, the technique of physical clamping entails fixing the periphery of the silicon carbide seed crystal 2 in place, using the graphite clamping accessory 4 by a means of screwing, so as to reduce stress unevenness, prevent formation of gas pores and solve the problems with the technique of applying adhesive. However, peripheral fixation causes a reduction in growth area to the detriment of crystal expansion experiments, and the most notorious drawback is the development of a peripheral grain boundary 9. The grain boundary 9 derives from the polycrystalline silicon carbide 8. It is because, in the course of the crystal growth of the graphite clamping accessory 4, the polycrystalline silicon carbide 8 accumulates on the graphite clamping accessory 4 to the detriment of the periphery of the monocrystalline silicon carbide 6 thus grown, leading to a great reduction in the available area of the monocrystalline silicon carbide 6; furthermore, the polycrystalline silicon carbide 8 and the grain boundary 9 increase the chance of developing crystal processing-related cracks.

The prior art discloses a technique of processing a silicon carbide seed crystal, such that the silicon carbide seed crystal growth surface protrudes from the graphite accessory clamping point. In the course of silicon carbide monocrystalline growth, silicon carbide monocrystalline is always higher than silicon carbide polycrystalline, to the monocrystalline silicon carbide will not have the defects of the polycrystalline silicon carbide and grain boundary defect. The prior art has difficulty in obtaining the silicon carbide seed crystal. First, to process raised silicon carbide seed crystals, it is necessary to acquire a specific thickness and ensure that cracks will not occur during the processing process, thereby incurring high production cost.

In conclusion, to overcome the aforesaid drawbacks of the conventional silicon carbide crystal growth methods, the present invention provides a method of enhancing silicon carbide monocrystalline growth yield.

### BRIEF SUMMARY OF THE INVENTION

An objective of the present disclosure is to provide a method of enhancing silicon carbide monocrystalline growth yield to physically clamp the silicon carbide seed crystal, reduce the chance of a fall of the silicon carbide seed crystal, and use the geometric configuration of the surface of the modification graphite seed crystal platform to prevent the development of the peripheral grain boundary and effectively enhance the crystal growth yield.

To achieve at least the above objective, the present disclosure provides a method of enhancing silicon carbide monocrystalline growth yield, comprising the steps of: (A) filling a bottom of a graphite crucible with a silicon carbide raw material selected; (B) performing configuration modification on a graphite seed crystal platform; (C) fastening a silicon carbide seed crystal to the modified graphite seed crystal platform with a graphite clamping accessory; (D) placing the graphite crucible containing the silicon carbide raw material and the silicon carbide seed crystal in an inductive high-temperature furnace; (E) performing silicon carbide crystal growth process by physical vapor transport; and (F) obtaining silicon carbide monocrystalline crystals.

Preferably, a space is formed at an edge of the graphite seed crystal platform, corresponds in position to a clamping point of the silicon carbide seed crystal, and is defined with a configuration width, a configuration depth and a configuration angle.

Preferably, the graphite seed crystal platform has an alignment depth and an alignment width which correspond to the silicon carbide seed crystal.

Preferably, the alignment width is greater than or equal to 1.5% of a diameter of the silicon carbide seed crystal.

Preferably, the configuration depth is greater than or equal to 3% of a diameter of the silicon carbide seed crystal.

Preferably, the configuration width is greater than or equal to 3% of a diameter of the silicon carbide seed crystal.

Preferably, the configuration angle is 1°˜90°.

### BRIEF DESCRIPTION OF THE DRAWINGS

FIG. 1 (PRIOR ART) is a schematic view of a conventional graphite seed crystal platform.

FIG. 2 (PRIOR ART) is a schematic view, depicting the difficulty in applying adhesive to a conventional silicon carbide seed crystal and fixing it in place.

FIG. 3 (PRIOR ART) is a schematic view, depicting the difficulty in applying adhesive to a conventional silicon carbide seed crystal and physically clamping it.

FIG. 4 is a schematic view of how to fix seed crystal in place, using sublimed silicon carbide, according to the present disclosure.

FIG. 5 is a schematic view of a graphite seed crystal platform of the present disclosure.

FIG. 6A shows picture taken of a conventional XRT wafer.

FIG. 6B shows picture taken of an XRT wafer of the present disclosure.

FIG. 7A shows the configuration and the dimension of a normal graphite seed crystal platform.

FIG. 7B shows the configuration and the dimension of a modification graphite seed crystal platform.

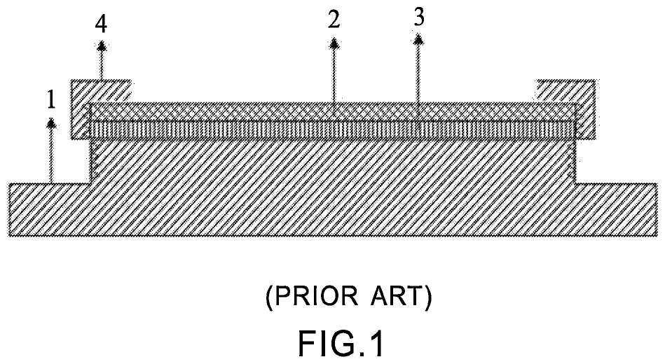

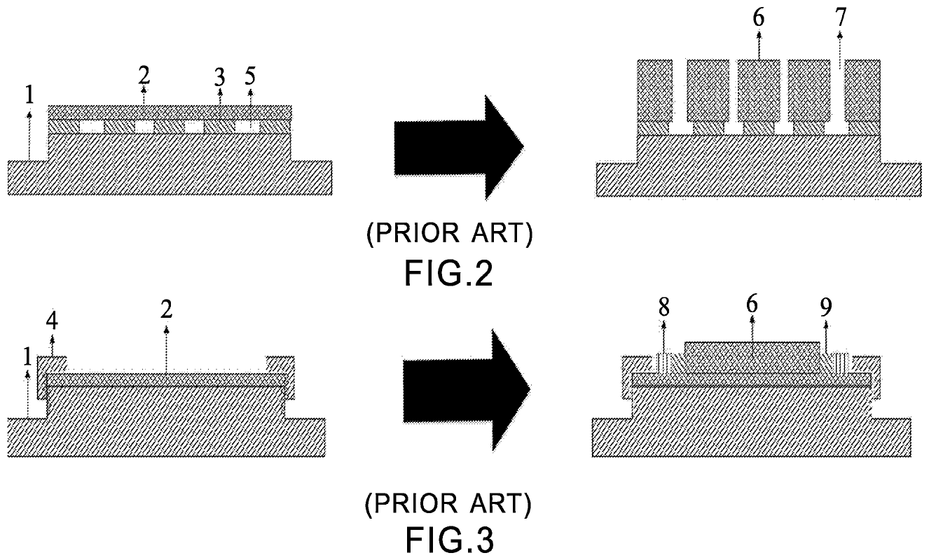

### DETAILED DESCRIPTION OF THE INVENTION

To facilitate understanding of the object, characteristics and effects of this present disclosure, embodiments together with the attached drawings for the detailed description of the present disclosure are provided.

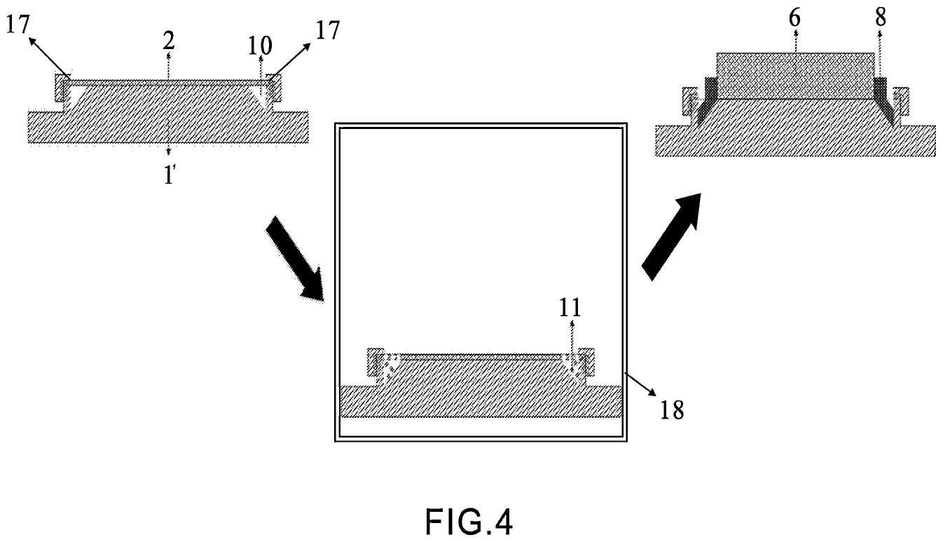

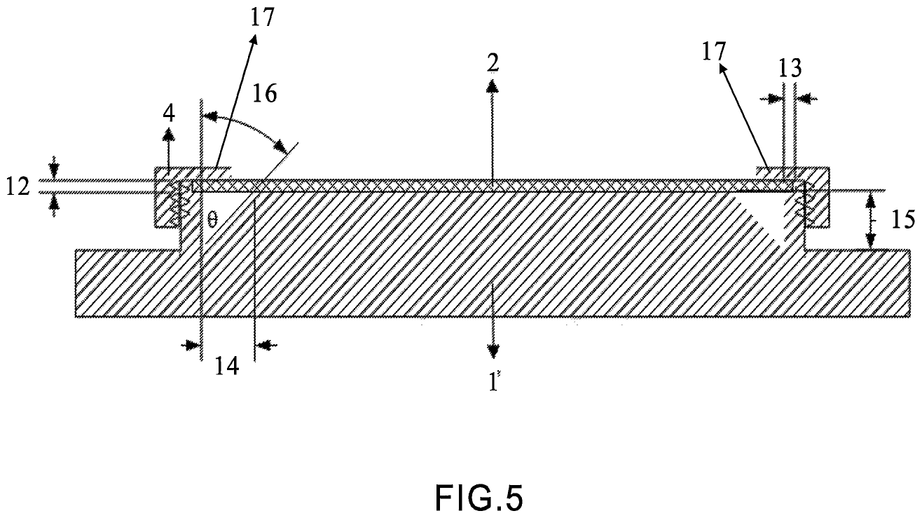

Refer to FIG. 4 and FIG. 5. FIG. 4 is a schematic view of how to fix seed crystal in place, using sublimed silicon carbide, according to the present disclosure. FIG. 5 is a schematic view of a graphite seed crystal platform of the present disclosure. The present disclosure provides a method of enhancing silicon carbide monocrystalline growth yield, comprising the steps of filling the bottom of the graphite crucible with a silicon carbide raw material and then performing configuration modification on a graphite seed crystal platform 1′, such that a space 10 is formed at the edge of the graphite seed crystal platform 1′ and corresponding in position to a clamping point of a silicon carbide seed crystal 2. The space 10 is defined by a configuration width 14, configuration depth 15 and configuration angle 16. The graphite seed crystal platform 1′ has an alignment depth 12 and alignment width 13 required for alignment of the silicon carbide seed crystal 2. The silicon carbide seed crystal 2 is fastened to the modified graphite seed crystal platform 1′ with a graphite clamping accessory 4. After that, a graphite crucible which contains a silicon carbide raw material and the silicon carbide seed crystal 2 is placed in an inductive high-temperature furnace. Next, a silicon carbide crystal growth process is carried out by physical vapor transport (PVT) to obtain silicon carbide monocrystalline crystals.

According to the present disclosure, the physical vapor transport (PVT) carried out to achieve silicon carbide monocrystalline growth is described below. The physically clamped silicon carbide seed crystal 2 is placed on the graphite seed crystal platform 1′ and then on the top of the graphite crucible; meanwhile, the silicon carbide raw material is placed in its bottom. The graphite crucible is depressurized, in the presence of inert gas, to less than 0.1˜50 Torr and heated up to 2000˜2400° C. to cause sublimation of the silicon carbide raw material and control the heat field to transfer the gas source to the surface of the silicon carbide seed crystal 2 for the sake of crystal growth. The present disclosure begins with physical clamping and entails modifying the geometric configuration of the surface of the graphite seed crystal platform 1′ to eradicate the development of peripheral grain boundary 9, thereby enhancing crystal growth yield.

In this embodiment, physical vapor transport (PVT) essentially attains the sublimation point of silicon carbide at high temperature and low pressure, such that the resultant gaseous silicon carbide moves toward a cooling zone of the graphite crucible and accumulates there. Then, given heat field control, a sublimed silicon carbide atmosphere 11 is guided to the silicon carbide seed crystal 2 and accumulates there, allowing silicon carbide monocrystalline growth to begin. Since the atmosphere 11 always moves toward the upper half of the graphite crucible, the silicon carbide eventually accumulates on the top of the graphite crucible. Thus, the silicon carbide seed crystal 2 has to lie at the uppermost end of the graphite crucible in order not to turn into the atmosphere 11 by sublimation and thereby accumulate at the top end.

According to the present disclosure, fixation of silicon carbide seed crystal 2 is initially achieved by physical clamping but subsequently by binding. In this regard, the binding process is carried out with polycrystalline silicon carbide 8 instead of graphite adhesive 3, as shown in FIG. 4, from left to right. First, the geometric configuration of the graphite seed crystal platform 1′ is modified to form the space 10, and then the silicon carbide seed crystal 2 is physically clamped thereto. Next, high-temperature, low-pressure silicon carbide growth takes place; meanwhile, the silicon carbide seed crystal 2 above the space 10 is gradually sublimed, and thus the resultant atmosphere 11 accumulates in accordance with the geometric configuration of the graphite seed crystal platform 1′. In this regard, peripheral sublimation of the polycrystalline silicon carbide 8 is accompanied by central growth of the monocrystalline silicon carbide 6 synchronously. At last, the monocrystalline silicon carbide 6 binds with the peripherally-located polycrystalline silicon carbide 8 so as to be fixed to the graphite seed crystal platform 1′.

Referring to FIG. 5, there is shown a schematic view of a graphite seed crystal platform of the present disclosure. As shown in the diagram, the silicon carbide seed crystal 2 is physically clamped to the modified graphite seed crystal platform 1′ with a graphite accessory. The modified graphite seed crystal platform 1′ has an alignment depth 12 and an alignment width 13 which correspond to the silicon carbide seed crystal 2. The alignment depth 12 is slightly less than the thickness of the silicon carbide seed crystal 2 and is intended to ensure the precise attachment of the graphite clamping accessory 4. The alignment width 13 depends on the diameter of the silicon carbide seed crystal 2. In this embodiment, the alignment width 13 is greater than or equal to 1.5% of the diameter of the silicon carbide seed crystal 2 and is intended to prevent the silicon carbide seed crystal 2 from bending because of the graphite clamping accessory 4. In case of excessive bending, the silicon carbide crystal growth will experience excessive stress and thus cause the development of defects or even cracks. The geometric configuration includes a configuration width 14, configuration depth 15 and configuration angle 16. The modification of configuration must be performed according to a principle: upon completion of the sublimation of the silicon carbide seed crystal 2, the polycrystalline silicon carbide 8 is precisely bound to the monocrystalline silicon carbide 6. Thus, in case of excessive configuration depth 15 and excessive configuration angle 16, the polycrystalline silicon carbide 8 has not yet bound with the edges of the monocrystalline silicon carbide 6 at the end of the sublimation of the silicon carbide seed crystal 2, thereby causing the silicon carbide seed crystal 2 to fall onto the surface of the silicon carbide raw material and fail. Conversely, insufficient configuration depth 15 and insufficient configuration angle 16 enable the polycrystalline silicon carbide 8 to bind with the edges of the monocrystalline silicon carbide 6 at the end of the sublimation of the silicon carbide seed crystal 2, but the polycrystalline silicon carbide 8 comes into contact with the monocrystalline silicon carbide 6 so soon to increase the chance of the grain boundary affecting the silicon carbide monocrystalline and decrease the available area of the silicon carbide crystal. Likewise, the configuration width 14, configuration depth 15 and configuration angle 16 depend on the diameter of the silicon carbide seed crystal 2. In this embodiment, the configuration depth 15 is greater than or equal to 3% of the diameter of the silicon carbide seed crystal 2, the configuration width 14 is greater than or equal to 3% of the diameter of the silicon carbide seed crystal 2, and the configuration angle 16 is 1°˜90°. The size of the graphite crucible depends on the target size of the silicon carbide crystal to grow. The weight and cross-sectional area of the silicon carbide raw material vary with the target size of the silicon carbide crystal to grow. Thus, the growth of larger silicon carbide crystal requires more silicon carbide atmosphere 11 and larger space 10 to prevent the overflow of the polycrystalline silicon carbide 8. Therefore, the present disclosure has advantages as follows: the polycrystalline silicon carbide 8 binds with the monocrystalline silicon carbide 6; the monocrystalline silicon carbide 6 has grown to acquire a certain thickness; the monocrystalline silicon carbide 6 is always higher than the polycrystalline silicon carbide 8 throughout the course of growth to thereby prevent the polycrystalline silicon carbide 8 from generating the grain boundary 9 which will otherwise affect the monocrystalline silicon carbide 6.

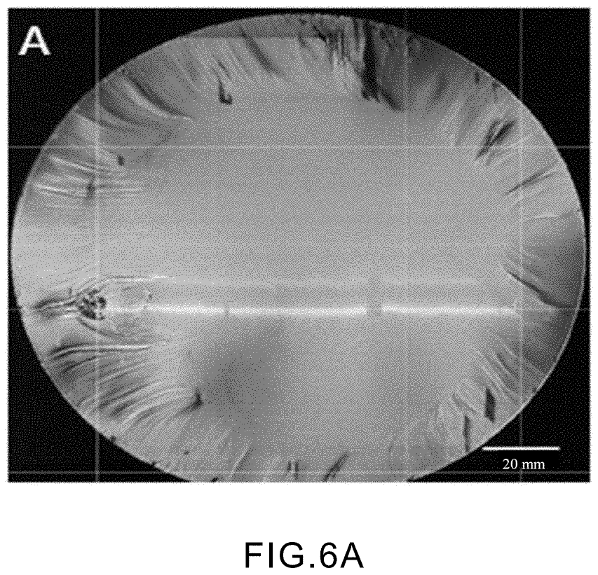

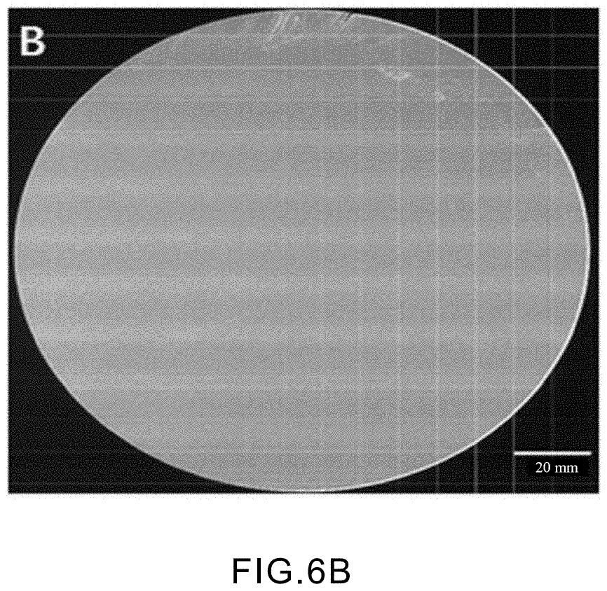

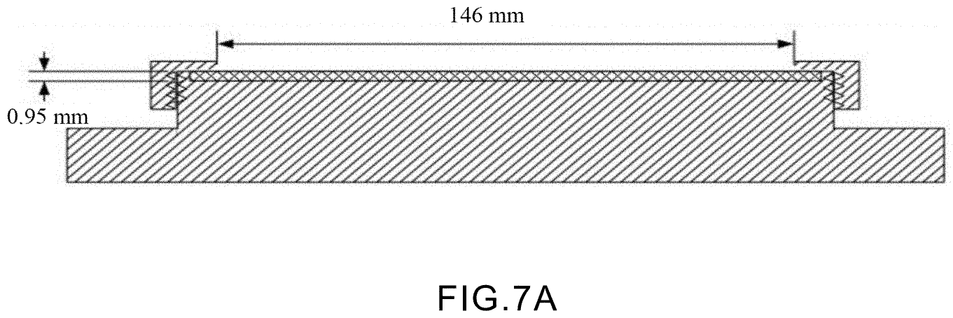

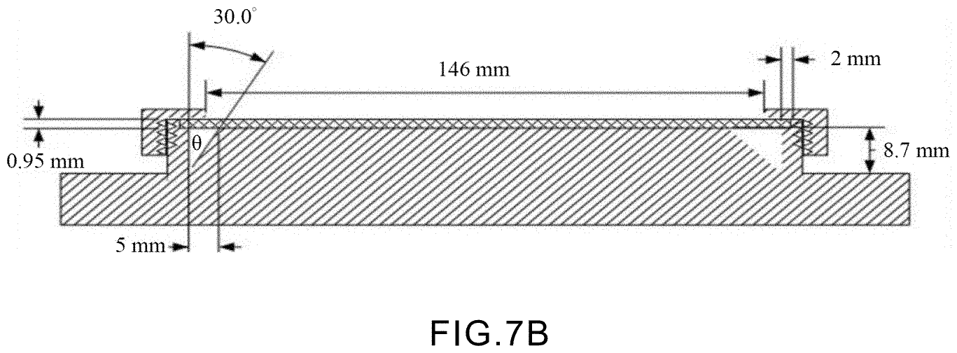

Referring to FIGS. 6A and 6B, FIG. 6A shows picture taken of a conventional XRT wafer; and FIG. 6B shows picture taken of an XRT wafer of the present disclosure. The present disclosure is based on two experiments: A: normal graphite seed crystal platform, as shown in FIG. 7A; B: modification graphite seed crystal platform, as shown in FIG. 7B. The modification graphite seed crystal platform has parameters as follows: an alignment width 13 of 2 mm, configuration width 14 of 5 mm, configuration depth 15 of around 8.7 mm, and configuration angle 16 of 30°. The silicon carbide seed crystal 2 with a diameter of 6 inches and a thickness of 1 mm is fastened to both the normal and modification graphite seed crystal platforms with the graphite clamping accessory 4. They are mounted on the graphite crucibles which contain 3 kg of silicon carbide raw material, respectively. The graphite crucibles, which are fully mounted in place, are encapsulated with a heat insulating material and placed in a heating furnace to undergo growth at temperature of around 2100˜2200° C. and pressure of 5 Torr. After the growth process has taken place for 70 hours, silicon carbide crystals of a thickness of 1.5 cm each are obtained.

The two silicon carbide crystals are cut at 1 cm above the seed crystal functioning as a standard surface. The resultant wafers undergo XRT inspection to observe the wafers' peripheral grain boundary and available area. Referring to FIGS. 6A and 6B, the wafer on the left is produced by the normal graphite seed crystal platform, whereas the wafer on the right is produced by the modification graphite seed crystal platform, showing conspicuously that in FIG. 6A the peripheral defects are much more serious than B, with the longest defect being nearly 3 cm long, causing a great reduction in the available area. In FIG. 6B, only the top shows some defects. Thus, the present disclosure is effective in enhancing the wafer yield.

In conclusion, the present disclosure provides a method of enhancing silicon carbide monocrystalline growth yield to physically clamp the silicon carbide seed crystal 2, reduce the chance of a fall of the silicon carbide seed crystal 2, and use the geometric configuration of the surface of the modification graphite seed crystal platform 1′ to prevent the development of the peripheral grain boundary 9 and effectively enhance the crystal growth yield.

While the present disclosure has been described by means of specific embodiments, numerous modifications and variations could be made thereto by those skilled in the art without departing from the scope and spirit of the present disclosure set forth in the claims.

1. A method of enhancing silicon carbide monocrystalline growth yield, comprising the steps of:
(A) filling a bottom of a graphite crucible with a silicon carbide raw material selected;
(B) performing configuration modification on a graphite seed crystal platform;
(C) fastening a silicon carbide seed crystal to the modified graphite seed crystal platform with a graphite clamping accessory;
(D) placing the graphite crucible containing the silicon carbide raw material and the silicon carbide seed crystal in an inductive furnace;
(E) performing silicon carbide crystal growth process by physical vapor transport; and
(F) obtaining silicon carbide monocrystalline crystals,
wherein the configuration modification in step (B) formed a space at an edge of the graphite seed crystal platform, corresponds in position to a clamping point of the silicon carbide seed crystal, and is defined with a configuration width, a configuration depth and a configuration angle;
wherein the configuration angle is substantially 30°,
such that when step (E) taking place, the silicon carbide seed crystal above the space is gradually sublimed, and the resultant atmosphere accumulates in accordance with the geometric configuration of the graphite seed crystal platform,
so that the silicon carbide monocrystalline crystals bind with peripherally-located polycrystalline silicon carbide so as to be fixed to the graphite seed crystal platform.

2. (canceled)

3. The method of enhancing silicon carbide monocrystalline growth yield according to claim 1, wherein the graphite seed crystal platform has an alignment depth and an alignment width which correspond to the silicon carbide seed crystal.

4. The method of enhancing silicon carbide monocrystalline growth yield according to claim 3, wherein the alignment width is greater than or equal to 1.5% of a diameter of the silicon carbide seed crystal.

5. The method of enhancing silicon carbide monocrystalline growth yield according to claim 2, wherein the configuration depth is greater than or equal to 3% of a diameter of the silicon carbide seed crystal.

6. The method of enhancing silicon carbide monocrystalline growth yield according to claim 2, wherein the configuration width is greater than or equal to 3% of a diameter of the silicon carbide seed crystal.

7. (canceled)
